(19) United States
(12) Patent Application Publication
(10) Pub. No.: US 2011/0281217 A1
(43) Pub. Date: Nov. 17, 2011

(54) NEGATIVE PHOTOSENSITIVE INSULATING RESIN COMPOSITION AND METHOD FOR PATTERNING USING THE SAME

(76) Inventor: Katsumi Maeda, Tokyo (JP)

(21) Appl. No.: 13/146,886

(22) PCT Filed: Jan. 14, 2010
(86) PCT No.: PCT/JP2010/050351

§ 371 Date: Jul. 28, 2011

(30) Foreign Application Priority Data
Jan. 29, 2009 (JP) 2009-018194
Jun. 17, 2009 (JP) 2009-144148

(51) Int. Cl. G03F 7/038; G03F 7/38

(52) U.S. Cl. 430/283.1; 430/325

(57) ABSTRACT

This invention relates to a negative photosensitive insulating resin composition characterized in that the composition comprises an alkali-soluble polymer having at least one repeating constitutional unit represented by the following general formula (1), a cross-linker and a photo-acid generator. The negative photosensitive insulating resin composition provides a film having excellent properties such as heat resistance, mechanical properties and electric properties, and can be alkali-developed to achieve high resolution.

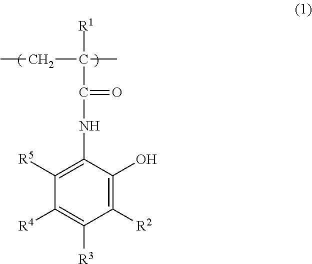

(In the formula, R¹ represents a hydrogen atom or a methyl group, and R² to R⁵ represent, independently each other, a hydrogen atom or a hydrocarbon group having 1 to 4 carbon atoms.)

### TECHNICAL FIELD

This invention relates to a photosensitive resin composition, and a patterning method, and particularly, a negative photosensitive resin composition applicable to an interlayer insulating film and a surface protection film of a semiconductor device and a method for forming pattern.

### BACKGROUND ART

Polyimide resins having excellent film properties such as heat resistance, mechanical properties and electric properties have been conventionally used for an interlayer insulating film or surface protection film of a semiconductor device. However, when a non-photosensitive polyimide resin is used as an interlayer insulating film or the like, a patterning process uses a positive resist, which requires etching and resist removal processes or the like, resulting in a more complex manufacturing process. The use of a photosensitive polyimide resin exhibiting excellent photo-sensitivity has investigated accordingly.

Such a photosensitive polyimide resin composition includes a positive photosensitive resin composition consisting of a polyamidic acid, an aromatic bisazide compound and an amine compound (See Patent Document 1). However, a development step in a patterning process of a photosensitive polyimide resin requires an organic solvent such as N-methyl-2-pyrrolidone and ethanol, which is problematic in terms of safety and environmental impact.

Thus, a photosensitive resin composition has recently been developed as a patterning material which can be developed with an aqueous alkaline solution such as an aqueous tetramethylammonium hydroxide (TMAH) solution used in a fine patterning process for a semiconductor. For example, a non-chemical amplified photosensitive resin composition consisting of a polybenzoxazole precursor and a diazoquinone compound as a photosensitizing agent (Patent Document 2), a non-chemical amplified photosensitive resin composition consisting of a polybenzoxazole precursor and a 1,2-naphthoquinonediazide-5-sulfonate (Non-Patent Document 1) and a chemical amplified photosensitive resin composition consisting of a polybenzoxazole precursor protected by an acid-decomposable group and a photo-acid generator (Non-Patent Document 2) are reported.

In such a photosensitive resin composition, its structure is changed by heating to form a benzoxazole ring, resulting in excellent heat resistance and electric properties. For example, a polybenzoxazole precursor described in Non-Patent Document 1 forms a benzoxazole ring by heating after development with an alkaline solution as shown in the following reaction schemes A1 and A2. Since the benzoxazole ring is a stable structure, an interlayer insulating film or surface protection film prepared using a photosensitive composition consisting of the polybenzoxazole precursor exhibits excellent film properties such as heat resistance, mechanical properties and electric properties.

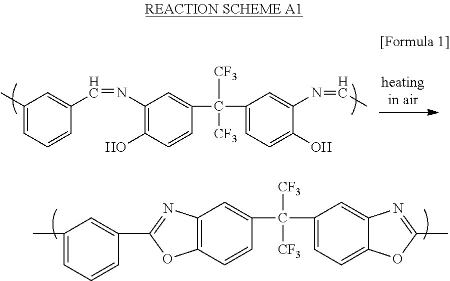

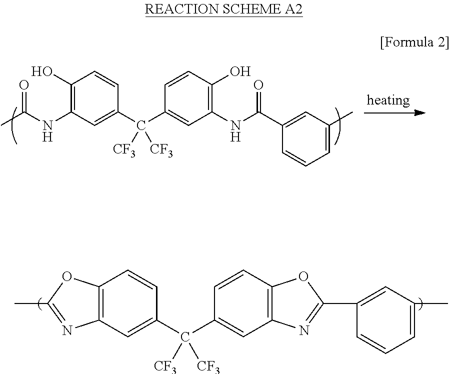

In the field of manufacturing a semiconductor device, recently, a higher density, a higher integration and a finer wiring pattern in the device have been further needed. Consequently, requirements have been stricter to a photosensitive insulating resin composition used for an interlayer insulating film, surface protection film or the like. However, in view of resolution, any positive photosensitive resin composition described in the above Documents is not satisfactory.

It is therefore waited to develop photosensitive resin compositions which can be developed with an alkaline solution and exhibit higher resolution, and further has the excellent adhesiveness on the substrate as the formed fine resin pattern is hard to strip off from the substrate, while maintaining the conventional film properties.

### PRIOR ART DOCUMENT

### Patent Document

Patent Document 1: JP3-36861B
Patent Document 2: JP1-46862B

### Non-Patent Document

Non-Patent Document 1: M. Ueda et al., Journal of Photopolymer Science and Technology, Vol. 16(2), pp. 237 to 242 (2003)
Non-Patent Document 2: K. Ebara et al., Journal of Photopolymer Science and Technology, Vol. 10(2), pp. 287 to 292 (2003)

### SUMMARY OF INVENTION

### Problems to be Solved by the Invention

Thus, this invention is achieved for solving the above problems, and a first object of this invention is to provide a photosensitive insulating resin composition exhibiting excellent film properties such as heat resistance, mechanical properties and electric properties, which can be developed with an alkaline solution and exhibit higher resolution, and further the formed fine resin pattern of which has excellent adhesiveness. A second object is to provide a method for patterning using the photosensitive insulating resin composition.

### Means to Solve the Problems

After intense investigation for achieving the above objects, the present inventor has found that a negative photosensitive insulating resin composition comprising an alkali-soluble polymer with a particular structure, a cross-linker and a photo-acid generator can be developed with an aqueous alkaline solution with higher resolution and has excellent adhesiveness on the substrate, and thus this invention has been achieved.

That is, this invention provides a negative photosensitive insulating resin composition characterized in that the resin composition comprises an alkali-soluble polymer, a cross-linker and a photo-acid-generator, wherein the alkali-soluble polymer has at least one repeating constitutional unit represented by the following general formula (1).

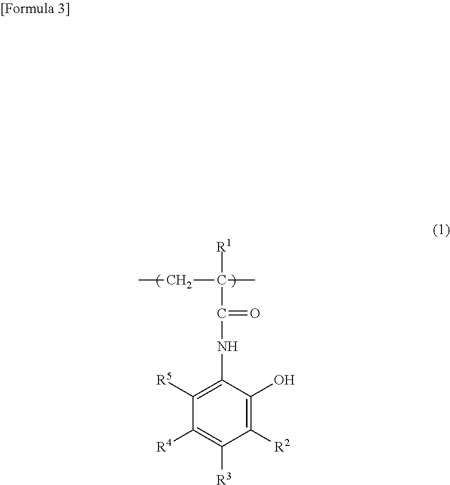

(In the formula (1), R¹ represents a hydrogen atom or a methyl group, and R² to R⁵ represent, independently each other, a hydrogen atom or a hydrocarbon group having 1 to 4 carbon atoms.)

This invention provides a negative photosensitive insulating resin composition characterized in that the cross-linker is a compound comprising the functional group represented by the following general formula (2), (3) or (4), a compound represented by the following general formula (5) or a compound comprising an epoxy group.

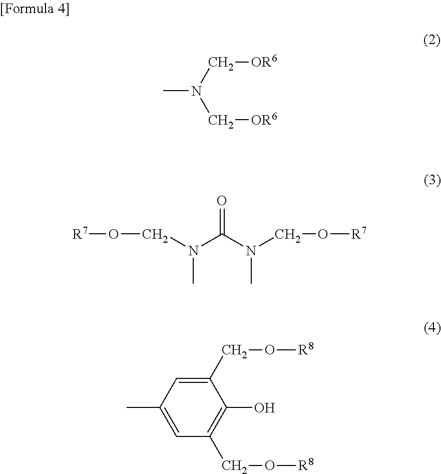

(In the formulae (2) to (4), R⁶, R⁷ and R⁸ represent an alkyl group having 1 to 6 carbon atoms respectively.)

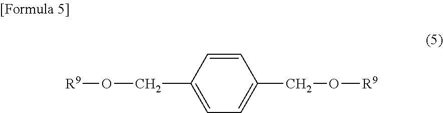

(In the formula (5), R⁹ represents an acyl group.)

The compound represented by the formula (2) is preferably a compound represented by the following formula (6).

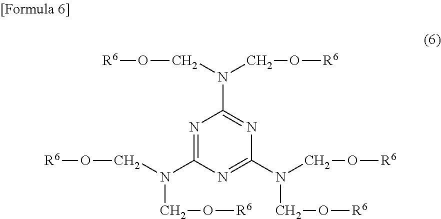

(In the formula (6), R⁶ represents an alkyl group having 1 to 6 carbon atoms.)

The compound represented by the formula is preferably a compound represented by any one of the following formulae (7) to (9).

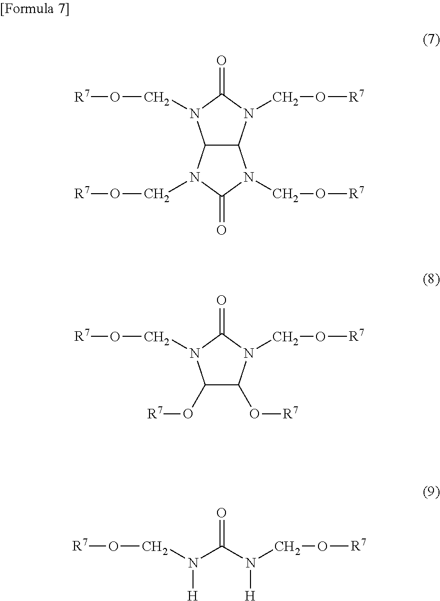

(In the formulae (7) to (9), R⁷ represents an alkyl group having 1 to 6 carbon atoms.)

The compound represented by the formula is preferably a compound represented by the following formula (10) or (11).

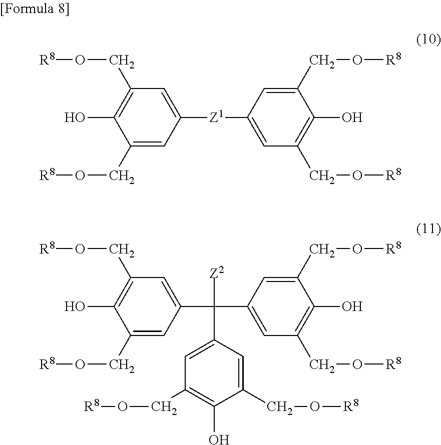

(In the formulae (10) and (11), R⁸ represents an alkyl group having 1 to 6 carbon atoms, Z¹ represents direct bond, —CH₂—, —(CH₃)₂— or —C(CF₃)₂—, and Z² represents a hydrogen atom or a methyl group.)

This invention provides the negative photosensitive insulating resin composition characterized in that the alkali-soluble polymer having at least one repeating constitutional unit represented by the general formula (1) is further comprising one or more of the repeating constitutional units selected from a repeating constitutional unit represented by the following general formula (12) and a repeating constitutional unit represented by the following general formula (13) with the repeating constitutional unit represented by the general formula (1).

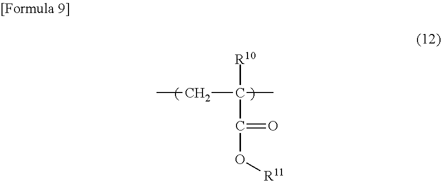

(In the formula (12). R¹⁰ represents a hydrogen atom or a methyl group, and R¹¹ represents an organic group having a lactone ring.)

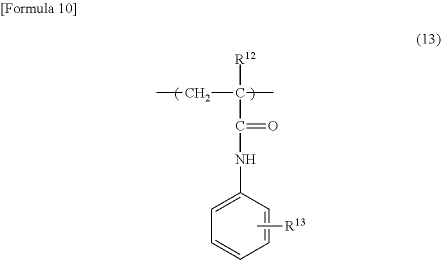

(In the formula (13), R¹² represents a hydrogen atom or a methyl group, and R¹³ represents a hydrogen atom, or an alkyl or alkoxy group having 1 to 4 carbon atoms.)

Furthermore, this invention provides a method for patterning characterized in that the patterning method comprises at least the steps of:

applying the above negative photosensitive insulating resin composition on a processed substrate;
pre-baking;
exposing;
after-exposure baking;
developing; and
post-baking.

### Effects of the Invention

The negative photosensitive insulating resin composition and the method for patterning of this invention can form the pattern with high resolution by means of developing with an alkaline developer, and can form the film which is excellent in heat resistance, mechanical properties and electric properties.

### EMBODIMENTS FOR CARRYING OUT THE INVENTION

Hereinafter, the negative photosensitive insulating resin composition and the method for patterning of this invention are explained.

### <Photosensitive Insulating Resin Composition>

The negative photosensitive insulating resin composition and the method for patterning of this invention contains an alkali-soluble polymer which comprises at least one repeating constitutional unit of the following general formula (1), a cross-linker and a photo-acid generator, and generally can be prepared by mixing the alkali-soluble polymer, the cross-linker and the photo-acid generator.

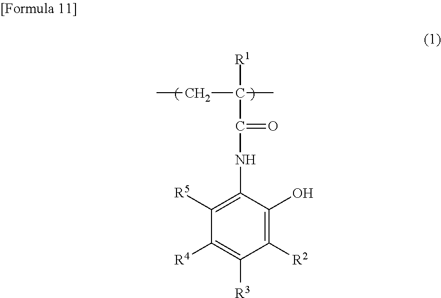

In Formula (1), R¹ represents a hydrogen atom or a methyl group, and R² to R⁵ represent, independently each other, a hydrogen atom or a hydrocarbon group having 1 to 4 carbon atoms.)

In the repeating constitutional unit represented by the formula (1) of the alkali-soluble polymer using in the negative photosensitive insulating resin composition of this invention, the hydrocarbon group having 1 to 4 carbon atoms represented by R² to R⁵ may include methyl, ethyl, n-propyl, isopropyl, n-butyl and tert-butyl groups.

Specific examples of the repeating constitutional unit represented by the general formula (1) may include, but not limited to, the examples shown in following Table 1.

TABLE 1

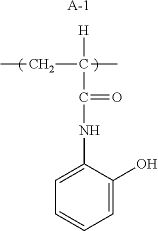

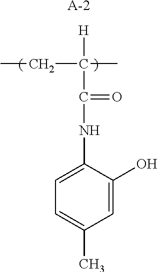

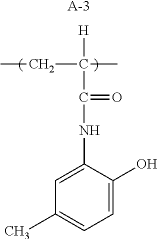

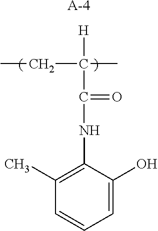

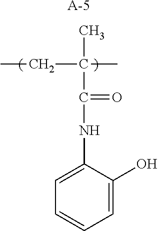

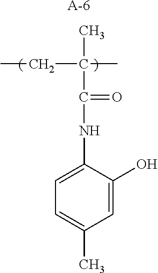

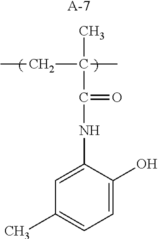

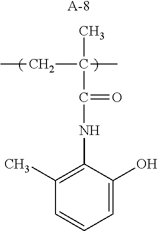

The alkali-soluble polymer used in this invention is heated after patterning to induce a ring-closing reaction into formation of a benzoxazole ring, and to form the film having excellent properties such as heat resistance, mechanical properties and electric properties.

For example, a polymer in which all R¹ to R⁵ are hydrogen atoms induces a ring-closing reaction by heating to form a benzoxazole ring as shown in the following Reaction Scheme B.

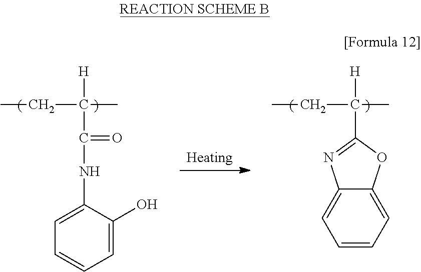

Since this benzoxazole ring is stable in a structure, using this polymer for an interlayer insulating film or surface protection film, the interlayer insulating film or surface protection film having excellent film properties such as heat resistance, mechanical properties and electric properties can be formed.

The raw material for the alkali-soluble polymer used in this invention is, but not limited to, the polymer comprising at least one repeating constitutional unit represented by the formula (1) and may be used suitably a (meth)acrylamide derivative represented by the general formula (14).

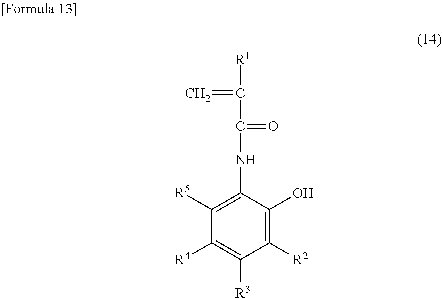

(In Formula (14), R¹ represents a hydrogen atom or a methyl group, and R² to R⁵ represent, independently each other, a hydrogen atom or a hydrocarbon group having 1 to 4 carbon atoms.)

The polymer comprising at least one repeating constitutional unit represented by the formula (1) used in this invention may be the polymer obtained by polymerizing only a (meth)acrylamide derivative represented by the general formula (14) or the copolymer obtained by copolymerizing with a co-monomer except the (meth)acrylamide derivative represented by the general formula (14). Since the copolymer is added the properties originated from the co-monomer, the polymer may be improved its properties useful for a photosensitive resin composition containing this polymer (e.g., resolution and sensitivity) and for an interlayer insulating film or surface protection film formed from this photosensitive resin (e.g., heat resistance, mechanical properties and electric properties) by using various co-monomers.

The co-monomer is preferably a vinyl monomer, because it is sufficiently polymerizable with the above (meth)acrylamide derivative. The vinyl monomer may include (meth)acrylamide derivatives other than the above (meth)acrylamide derivative, butadiene, acrylonitrile, styrene, (meth)acrylic acid, ethylene derivatives, styrene derivatives, (meth)acrylate derivatives and the like.

The ethylene derivatives can include ethylene, propylene and vinyl chloride, and the styrene derivative may include α-methylstyrene, p-hydroxystyrene, chlorostyrene and styrene derivatives described in JP2001-172315A.

In addition to a vinyl monomer, maleic anhydride and N-phenylmaleimide derivatives are usable. The N-phenylmaleimide derivatives may include N-phenylmaleimide and N-(4-methylphenyl)maleimide.

These co-monomers can be used one kind, and may be used 2 or more kinds.

Specific examples of the repeating constitutional unit from the above co-monomer may be mentioned a constitutional unit derived from a (meth)acrylate having a lactone ring represented by the following general formula (12) and a constitutional unit derived from a (meth)acrylamide derivative represented by the following general formula (13).

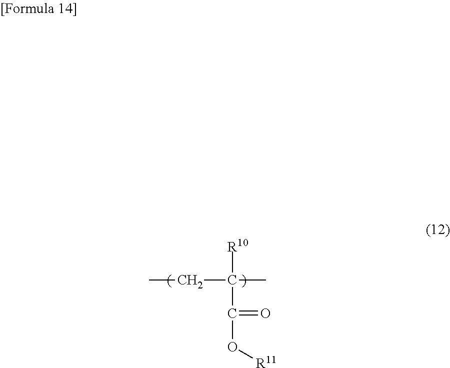

(In the formula (12), R¹⁰ represents a hydrogen atom or a methyl group, and R¹¹ represents an organic group having a lactone structure.)

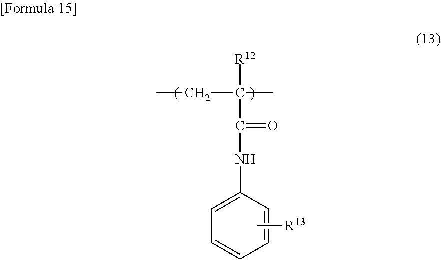

(In the formula (13), R¹² represents a hydrogen atom or a methyl group, and R¹³ represents a hydrogen atom or an alkyl or alkoxy group having 1 to 4 carbon atoms.)

The repeating constitutional unit represented by the general formula may, but not limited to, include the examples shown in the following Table 2.

TABLE 2

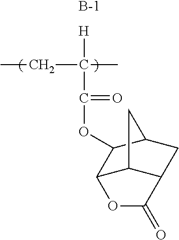

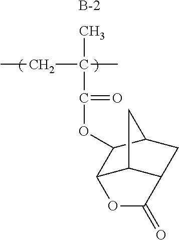

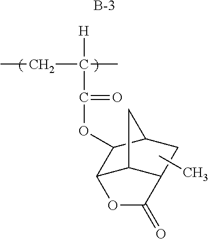

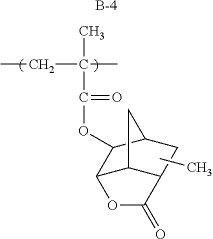

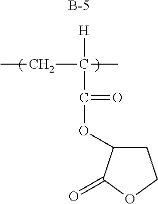

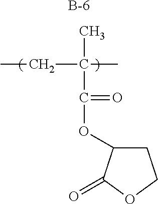

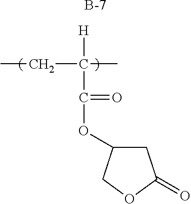

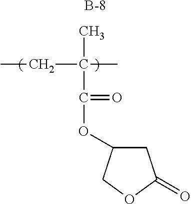

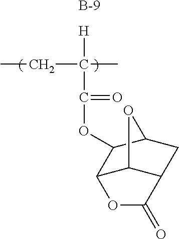

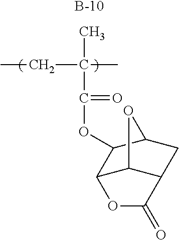

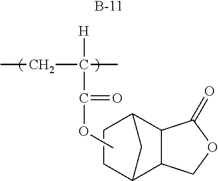

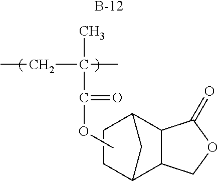

The repeating constitutional unit represented by the general formula (13) may, but not limited to, include the examples shown in the following Table 3.

TABLE 3

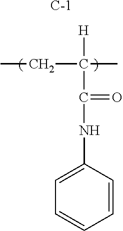

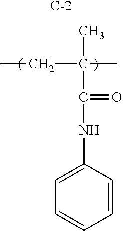

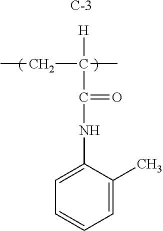

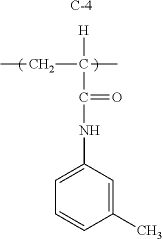

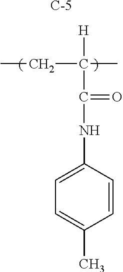

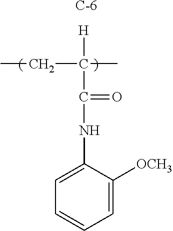

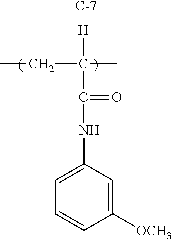

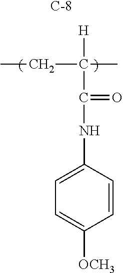

To achieve excellent film properties when the alkali-soluble polymer used in this invention is used for an interlayer insulating film or surface protection film, the content of the repeating constitutional unit represented by the general formula (1) in the polymer is preferably 10 to 100 mol %, more preferably 20 to 100 mol %.

The weight average molecular weight (Mw) of the alkali-soluble polymer is generally preferably 2,000 to 200,000, more preferably 4,000 to 100,000. If Mw of the polymer is less than 2,000, it is unable to form homogeneously an interlayer insulating film or surface protection film. If Mw of the polymer is more than 200,000, resolution in forming the interlayer insulating film or the surface protection film may deteriorate.

The alkali-soluble polymer comprising at least one repeating constitutional unit represented by the formula (1) can be obtained by polymerizing the monomer composition containing the above (meth)acrylamide derivative via a commonly used polymerization process such as radical polymerization and anion polymerization.

For example, by the radical polymerization, an appropriate radical polymerization initiator such as 2,2′-azobis(isobutyronitrile) is added to a dry tetrahydrofuran in which the monomer composition containing the above (meth)acrylamide derivative is dissolved, and the mixture can be then stirred at 50 to 70° C. for 0.5 to 24 hours under an atmosphere of an inert gas such as argon and nitrogen to give the polymer.

As the cross-linker used in the present application, firstly, the compound comprising the functional group represented by the following general formula (2) may be mentioned.

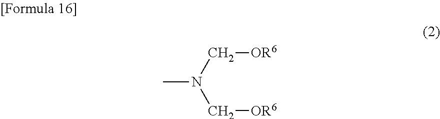

(In the formula (2), R⁶ represents an alkyl group having 1 to 6 carbon atoms.)

As the compound comprising the functional group represented by the general formula (2), specifically the compound represented by the following general formula (6) may be mentioned.

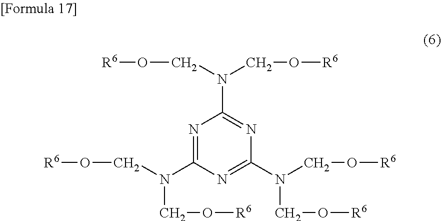

(In the formula (6), R⁶ represents an alkyl group having 1 to 6 carbon atoms.)

The alkyl group having 1 to 6 carbon atoms is, specifically, for example, a methyl group, an ethyl group, an n-propyl group, an isopropyl group, an n-butyl group, a tert-butyl group, pentyl group, hexyl group and the like.

As the cross-linker used in the present application, the compound comprising the functional group represented by the following general formula (3) may also be mentioned.

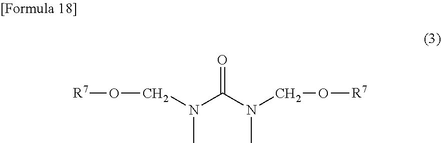

(In the formula (3), R⁷ represents an alkyl group having 1 to 6 carbon atoms.)

As the compound comprising the functional group represented by the general formula (3), specifically the compound represented by any one of the following general formulae (7) to (9) may be mentioned.

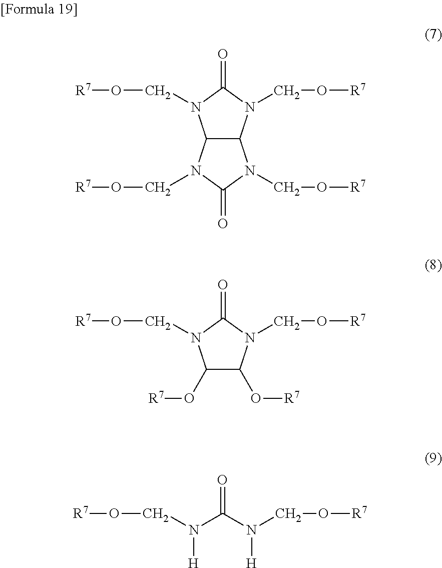

(In the formulae (7) to (9), R⁷ represents an alkyl group having 1 to 6 carbon atoms.)

The alkyl group having 1 to 6 carbon atoms is, specifically, for example, a methyl group, an ethyl group, an n-propyl group, an isopropyl group, an n-butyl group, a tert-butyl group, pentyl group, hexyl group and the like.

Further, as the cross-linker used in the present application, the compound comprising the functional group represented by the following general formula (4) may be mentioned.

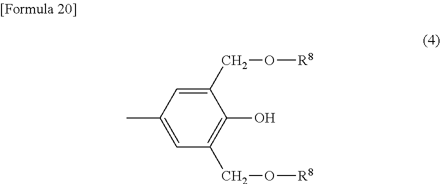

(In the formula (4), R⁷ represents an alkyl group having 1 to 6 carbon atoms.)

As the compound comprising the functional group represented by the general formula (4), specifically the compound represented by the following general formula (10) or (11) may be mentioned.

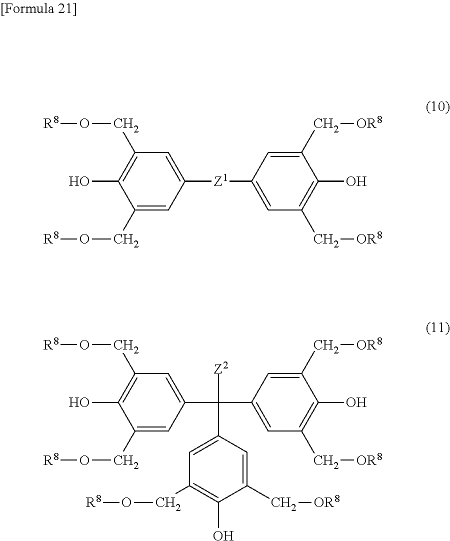

(In the formulae (10) and (11), R⁸ represents an alkyl group having 1 to 6 carbon atoms. Z¹ represents direct bond, —CH₂—, —C(CH₃)₂— or —C(CF₃)₂—, and Z² represents a hydrogen atom or methyl group.)

The alkyl group having 1 to 6 carbon atoms is, specifically, for example, a methyl group, an ethyl group, an n-propyl group, an isopropyl group, an n-butyl group, a tert-butyl group, pentyl group, hexyl group and the like.

In addition, as the cross-linker used in the present application, the compound represented by the following general formula (5) also is usable.

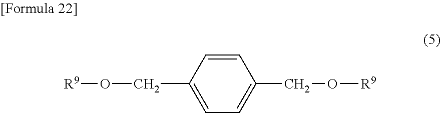

(In the formula (5), R⁹ represents an acyl group.)

The acyl group may include an acetyl group, propionyl group, butyryl group and the like.

The compound being usable as the cross-linker in this invention and comprising an epoxy group is the compound generally so-called as an epoxy compound and/or resin (in this application, without notification, calls as an “epoxy compound”), and may be specifically exemplified the followings; bisphenol A diglycidyl ether, hydrogenated bisphenol A diglycidyl ether, bisphenol F diglycidyl ether, bisphenol A propoxylate diglycidyl ether, ethylene glycol diglycidyl ether, diethylene glycol diglycidyl ether, propylene glycol diglycidyl ether, tripropylene glycol diglycidyl ether, neopentyl glycol diglycidyl ether, 1,6-hexanediol diglycidyl ether, glycerin diglycidyl ether, trimethylolpropane triglycidyl ether, diglycidyl 1,2-cyclohexanedicarboxylate, 3,4-epoxycyclohexylmethyl 3,4-epoxycyclohexanecarboxylate, trisepoxypropyl isocyanulate, 2-epoxyethyl bicyclo[2,2,1]heptyl glycidyl ether, ethylene gycol bis(2-epoxyethyl bicyclo[2,2,1]heptyl)ether, bis(2-epoxyethyl bicyclo[2,2,1]heptyl) ether or the like.

When the cross-linker is added, the content is ordinary 0.5 to 50 parts by mass relative to 100 parts by mass of the all components including the cross-linker itself, and preferably 1 to 40 parts by mass. The cross-linker may be used alone or in combination with two or more.

A photo-acid generator used in this invention preferably generates an acid by irradiation with light used for exposing. As long as the photo-acid generator may be any of them whose mixture with a polymer of this invention is adequately soluble in an organic solvent and the solution obtained can be used to form a homogeneous coating film by a film forming method such as spin coating, the photo-acid generator is not particularly limited. The photo-acid generator may be used alone or in combination with two or more. Specifically, the photo-acid generator includes, but not limited to, triarylsulfonium salt derivatives, diaryliodonium salt derivatives, dialkylphenacylsulfonium salt derivatives, nitrobenzyl sulfonate derivatives, sulfonate derivatives of N-hydroxynaphthalimide and sulfonate derivatives of N-hydroxysuccinimide.

The content of the photo-acid generator is preferably not less than 0.2% by mass, more preferably not less than 0.5% by mass to the total of the alkali-soluble polymer, the cross-linker and the photo-acid generator in view of achieving adequate sensitivity of the negative photosensitive insulating resin composition and satisfactory patterning. On the other hand, it is preferably not more than 30% by mass, more preferably not more than 15% by mass in view of forming a homogeneous coating film and preventing a residue (scum) after development.

When the negative photosensitive insulating resin composition is pattern-exposed by the chemical ray described below, an acid generates from the photo-acid generator constituting the negative photosensitive insulating resin composition, and the generated acid conducts the cross-linking reaction between the resin and the cross-linker. As the result, the exposed area becomes hard-solving to the alkaline developer, and the solubility difference between the exposed area and the unexposed area (solubility contrast) occurs. The patterning using this negative photosensitive insulating resin composition is conducted by application of this solubility difference agent the alkaline developer.

An appropriate solvent may be, if necessary, used in preparation of the negative photosensitive insulating resin composition of this invention.

As the solvent, any organic solvent may be used without limitations as long as it can adequately dissolve the negative photosensitive insulating resin composition, a resultant solution can be used to form a homogeneous film by, for example, spin coating. Specific examples include γ-butyrolactone, propylene glycol monomethyl ether acetate, propylene glycol monoethyl ether acetate, ethyl lactate, 2-heptanone, 2-methoxybutyl acetate, 2-ethoxyethyl acetate, methyl pyruvate, ethyl pyruvate, methyl 3-methoxypropionate, ethyl 3-methoxypropionate, N-methyl-2-pyrrolidone (NMP), cyclohexanone, cyclopentanone, methyl isobutyl ketone (MIBK), ethylene glycol monomethyl ether, ethylene glycol monomethyl ether acetate, ethylene glycol monoethyl ether, ethylene glycol monoisopropyl ether, diethylene glycol monomethyl ether and diethylene glycol dimethyl ether. These may be used alone or in combination of two or more.

Furthermore, the negative photosensitive insulating resin composition may contain, if necessary, other components such as a dissolution promoter, a dissolution inhibitor, an adhesion improver, a surfactant, a pigment, a stabilizer, a coating modifier and a dye.

For example, the adhesion of a harden film to a substrate can be improved by adding an adhesion improver composed of an organosilicon compound to a negative photosensitive resin composition.

The organosilicon compound may include, but not limited to, γ-aminopropyltrimethoxysilane, γ-aminopropyltriethoxysilane, vinyltriethoxysilane, an organosilicon compound described in Japanese Patent No. 3422703, and an organosilicon compound represented by the following general formula (15).

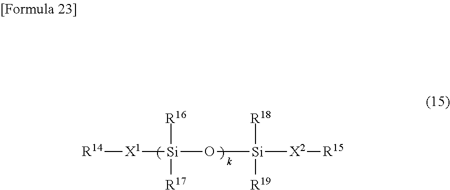

(In the formula (15), R¹⁴ to R¹⁹ represent a monovalent organic group, X¹ and X² represent a divalent organic group, and k represents a positive integer.)

The monovalent organic group represented by R¹⁶ to R¹⁹ may include an alkyl group such as methyl group, ethyl group, propyl group and butyl group, an aryl group such as phenyl group, tryl group, and naphthyl group, and the like.

The divalent organic group represented by X¹ and X² may include an alkylene group such as methylene group, ethylene group, propylene group and butylene group, an arylene group such as phenylene group, and the like.

The monovalent organic group represented by R¹⁴ and R¹⁵ may be mentioned specifically a monovalent organic group having an imide or amide bond represented by the following structure.

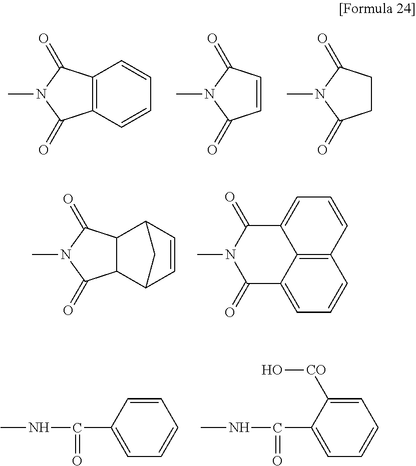

When the adhesion improver is added to the negative photosensitive insulating resin composition, the content is preferably not less than 0.1% by mass relative to the total of the alkali-soluble polymer, the cross-linker and the photo-acid generator in view of enabling the formation of the pattern having excellent adhesion, and more preferably not less than 0.5% by mass. Its content is preferably not more than 25% by mass in order to enable excellent resolution, and more preferably not more than 15% by mass.

The negative photosensitive insulating resin composition of this invention gives excellent pattern resolution, can be developed with an alkaline developer and also has the excellent adhesiveness of the formed pattern for the substrate. The film formed from the negative photosensitive insulating resin composition of this invention gives excellent film properties such as heat resistance, mechanical properties and electric properties. Thus, such a negative photosensitive insulating resin composition is suitable for making an interlayer insulating film or surface protection film.

### <Method for Patterning>

The method for patterning of this invention has at least an application step, a pre-bake step, an exposure step, an after-exposure bake step, a development step and a post-bake step.

In particular, the method for patterning of this invention comprises at least:

an application step of applying the above negative photosensitive insulating resin composition on a processed substrate;

a pre-bake step of fixing the negative photosensitive insulating resin composition film on the processed substrate:

an exposure step of selectively exposing the negative photosensitive insulating resin composition film;

an after-exposure bake step of baking the negative photosensitive insulating resin composition film after exposure;

a development step of dissolving and removing the unexposed area in the negative photosensitive insulating resin composition film to form a pattern; and

a post-bake step of hardening the patterned negative photosensitive resin composition film.

In the application step, the above negative photosensitive insulating resin composition is applied on a processed substrate such as a silicon wafer and a ceramic substrate. Application may be carried out by spin coating using a spin coater, spray coating using a spray coater, immersion, printing and roll coating.

In the pre-bake step, the negative photosensitive insulating resin composition applied on the processed substrate is dried to remove a solvent to fix the negative photosensitive insulating resin composition film on the processed substrate. The pre-bake step is generally carried out at 60 to 150° C.

In the exposure step, the negative photosensitive insulating resin composition film is selectively exposed via a photomask to form an exposed area and an unexposed area, to transfer a pattern in a photomask to the negative photosensitive insulating resin composition film. Chemical rays used in the pattern exposure include ultraviolet ray, visible light ray, Excimer laser, electron beam ray and X-ray, and preferably chemical rays having a wavelength of 180 to 500 nm.

The after-exposure bake step promotes the cross-linking reaction between the alkali-soluble polymer and the cross-linker by means of catalytic activity of the acid generated by exposing. The after-exposure bake step is generally carried out at 60 to 150° C.

In the development step, an unexposed area in the negative photosensitive insulating resin composition film is dissolved and removed in an alkaline developer to form a pattern. The above exposure step generates solubility difference (solubility contrast) of a polymer in an alkaline developer between an exposed area and an unexposed area in the negative photosensitive insulating resin composition film. Utilizing the solubility contrast, the unexposed area in the negative photosensitive insulating resin composition film is removed by dissolution to obtain the harden film of the negative photosensitive insulating resin composition film having a pattern formed (hereinafter, simply referred to “pattern”). Examples of the alkaline developer include an aqueous solution of a quaternary ammonium salt such as tetramethylammonium hydroxide (TMAH) and tetraethylammonium hydroxide or an aqueous solution further adding an appropriate amount of an additive such as water-soluble alcohols, for example, methanol and ethanol, and surfactants to the above solution. Development can be achieved by the method, such as paddling, immersing and spraying. After developed, the formed pattern is rinsed with water.

In the post-bake step, the obtained pattern is heated in the air or under an atmosphere of an inert gas, such as nitrogen, to improve adhesiveness of the pattern to the processed substrate and to cure the pattern. In the post-bake step, by heating the pattern formed from the negative photosensitive insulating resin composition, an alkali-soluble polymer contained in the negative photosensitive insulating resin composition is changed in structure (denatures), and a benzoxazole ring is formed therein, to cure the pattern. Thus, a pattern having excellent film properties such as heat resistance, mechanical properties and electric properties can be obtained. The post-bake step is generally carried out at 100 to 380° C. The post-bake step may be conducted in one step or in multiple steps.

### EXAMPLES

Hereinafter, this invention will be more specifically described by Examples.

### Synthetic Example 1

Synthesis of polymer A having 100 mol % of a constitutional unit (A-1 in Table 1) in which R¹ to R⁵ are hydrogen atoms in the general formula (1) (following, the number attached to the repeating unit represents mol %)

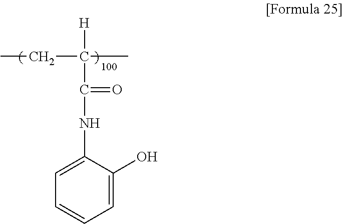

In 100 mL of tetrahydrofuran were dissolved 30 g of N-(2-hydroxyphenyl)acrylamide, then 0.603 g of 2,2′-azobis(isobutyronitrile) was added therein, and the mixture was heated at reflux under an argon atmosphere for 4 hours. After cooled, it was re-precipitated in 1000 mL of diethyl ether. The precipitated polymer was filtered and again purified by re-precipitation, to give 28 g of the polymer A (yield: 93%). By GPC analysis, the weight average molecular weight (Mw) of the polymer is 5100 (as polystyrene), and the dispersion (Mw/Mn) of the polymer is 2.38.

### Synthetic Example 2

Synthesis of polymer B having 70 mol % of a constitutional unit (A-1) in which R¹ to R⁵ are hydrogen atoms in the general formula (1) and 30 mol % of a constitutional unit (B-1 in Table 2) in which R¹⁰ is a hydrogen atom and R¹¹ is a 2,6-norbonane lactone-5-yl group in the general formula (12) (following, the numbers attached to the repeating unit represent mol %)

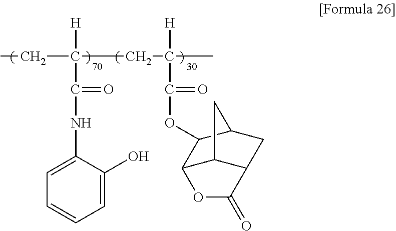

In 72 mL of terahydrofuran were resolved 20 g of N-(2-hydroxyphenyl)acrylamide and 10.94 g of 5-acroyloxy-2,6-norbonane lactone, then 0.288 g of 2,2′-azobis(isobutyronitrile) was added therein, and the mixture was heated at reflux under an argon atmosphere for 4 hours. After cooled, it was re-precipitated in 700 mL of diethyl ether. The precipitated polymer was filtered and again purified by re-precipitation, to give 28.46 g of the polymer B (yield: 92%). Mw of the polymer is 26500 (as polystyrene), and Mw/Mn of the polymer is 3.08.

### Synthetic Example 3

Synthesis of polymer C having 70 mol % of a constitutional unit (A-2 in Table 1) in which R¹ is a methyl group and R² to R⁵ are hydrogen atoms in the general formula (1) and 30 mol of a constitutional unit (B-1) in which R¹⁰ is hydrogen atom and R¹¹ is a 2,6-norbonane lactone-5-yl group in the general formula (12) (following, the numbers attached to the repeating unit represent mol %)

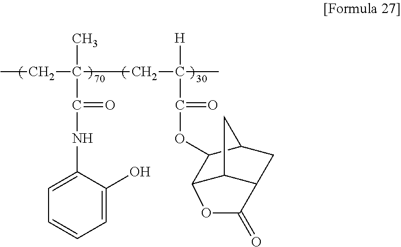

The polymerization was carried out in the same manner as in Synthetic Example 2 except that 21.71 g of N-(2-hydroxyphenyl)methacrylamide was used in place of N-(2-hydroxyphenyl)acrylamide to give 17.58 g of the polymer C (Yield 79%). Mw of the polymer is 21800 (as polystyrene), and Mw/Mn of the polymer is 2.78.

### Synthetic Example 4

Synthesis of polymer D having 70 mol % of a constitutional unit (A-1) in which R¹ to R⁵ are hydrogen atoms in the general formula (1) and 30 mol % of a constitutional unit based on styrene (following, the numbers attached to the repeating unit represent mol

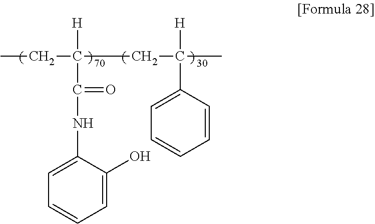

The polymerization was carried out in the same manner as in Synthetic Example 2 except that 5.47 g of styrene was used in place of 5-acroyloxy-2,6-norbonane lactone to give 21.9 g of the polymer D (Yield 86%). Mw of the polymer is 20800 (as polystyrene), and Mw/Mn of the polymer is 3.25.

### Synthetic Example 5

Synthesis of polymer E having 70 mol % of a constitutional unit (A-1) in which R¹ to R⁵ are hydrogen atoms in the general formula (1) and 30 mol % of a constitutional unit based on N-phenyacrylamide (following, the numbers attached to the repeating unit represent mol %)

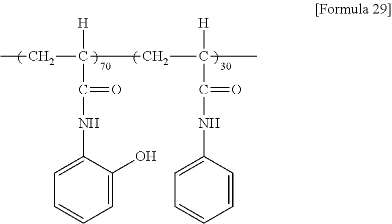

The polymerization was carried out in the same manner as in Synthetic Example 2 except that 8.21 g of N-phenylacrylamide was used in place of 5-acroyloxy-2,6-norbonane lactone to give 25.6 g of the polymer E (Yield 91%). Mw of the polymer is 20100 (as polystyrene), and Mw/Mn of the polymer is 3.15.

### Example 1

The negative photosensitive resin composition was prepared in such a way that (a) 10 g of the polymer A obtained in the Synthetic Example 1, (b) 1.5 g of a compound “NIKALAC MW-390” (Trade name, a product of Sanwa Chemicals Co. Ltd.) in which R⁶ is a methyl group in the general formula (6) as a cross-linker and (c) 0.2 g of a photo-acid generator, N-(trifluoromethanesulfonyloxy)naphthalimide “NAI-105” (Trade name, a product of Midori Kagaku Co., Ltd.) were dissolved in 7.25 g of γ-butyrolactone and then filtrated through a 0.2 μm of Teflon® filter.

On a 5 inch silicon substrate was spin-coated this negative photosensitive resin composition and then dried in an oven at 110° C. for 20 minutes to form a thin film having its thickness of 9.4 μm. Then the film was patterned by exposure with ultraviolet ray (wave length of 350 to 450 nm) via a photomask. After the exposure, it was baked in an oven at 100° C. for 10 minutes and then developed in a 2.38% of tetramethylammonium hydroxide (TMAH) at room temperature for 2 minutes, and then rinsed with pure water for 3 minutes. As a result, an unexposed area in the photosensitive resin composition film was dissolved off in the developing solution to obtain a negative pattern. SEM observation of the obtained pattern indicated that resolution to 15 μm of through-hole pattern was achieved at a sensitivity of 800 J/cm².

Next, the patterned wafer was baked under a nitrogen atmosphere in an oven at 100° C. for 1 hour and then at 220° C. for 1 hour for forming a benzoxazole ring to obtain a final pattern having a film thickness of 8 μm and exhibiting excellent properties such as heat resistance. SEM observation of the formed pattern did not indicate any crack and any delamination in the pattern.

### Example 2

The negative resin composition was prepared in the same manner as in Example 1 except that the polymer B obtained in Synthetic Example 2 was used as (a) the polymer and 1.5 g of the compound “TMOM-BP” (trade name, a product of HONSHU Chemical Industry Co. Ltd.) in which Z¹ is direct bond and R⁸ is a methyl group in the general formula (10) as (b) the cross-linker, spin-coated and then pattern-exposed to obtain a negative pattern. Table 4 shows the evaluation results for its sensitivity and resolution in a through-hole pattern.

The obtained pattern was baked under a nitrogen atmosphere in an oven at 100° C. for 1 hour and then at 220° C. for 1 hour for forming a benzoxazole ring to obtain a final pattern exhibiting excellent properties such as heat resistance. SEM observation of the formed pattern did not indicate any crack and any delamination in the pattern.

### Example 3

The negative resin composition was prepared in the same manner as in Example 1 except that the polymer C obtained in Synthetic Example 3 was used as (a) the polymer and 1.5 g of the compound “NIKALAC MW-270” (Trade name, a product of Sanwa Chemicals Co. Ltd.) in which R⁷ is a methyl group in the general formula (7) as (b) the cross-linker, spin-coated and then pattern-exposed to obtain a negative pattern. Table 4 shows the evaluation results for its sensitivity and resolution in a through-hole pattern.

The patterned wafer was baked under a nitrogen atmosphere in an oven at 100° C. for 1 hour and then at 220° C. for 1 hour for forming a benzoxazole ring to obtain a final pattern exhibiting excellent properties such as heat resistance. SEM observation of the formed pattern did not indicate any crack and any delamination in the pattern.

### Example 4

The negative resin composition was prepared in the same manner as in Example 1 except that the polymer D obtained in Synthetic Example 4 was used as (a) the polymer and 1.5 g of the compound 1,4-bis(acetoxymethyl)benzene in which R⁹ is a acetyl group in the general formula (5) as (b) the cross-linker, spin-coated and then pattern-exposed to obtain a negative pattern. Table 4 shows the evaluation results for its sensitivity and resolution in a through-hole pattern.

The patterned wafer was baked under a nitrogen atmosphere in an oven at 100° C. for 1 hour and then at 220° C. for 1 hour for forming a benzoxazole ring to obtain a final pattern exhibiting excellent properties such as heat resistance. SEM observation of the formed pattern did not indicate any crack and any delamination in the pattern.

### Example 5

The negative resin composition was prepared in the same manner as in Example 1 except that the polymer E obtained in Synthetic Example 5 was used as (a) the polymer and 1.5 g of bisphenol F diglycidyl ether as (b) the cross-linker, spin-coated and then pattern-exposed to obtain a negative pattern. Table 4 shows the evaluation results for its sensitivity and resolution in a through-hole pattern.

The patterned wafer was baked under a nitrogen atmosphere in an oven at 100° C. for 1 hour and then at 220° C. for 1 hour for forming a benzoxazole ring to obtain a final pattern exhibiting excellent properties such as heat resistance. SEM observation of the formed pattern did not indicate any crack and any delamination in the pattern.

TABLE 4

| | Photosensitive insulating resin | | | | | | |
|---|---|---|---|---|---|---|---|
| | composition | | | | | | |
| | | | Photo- | Patterning | | | |
| | | | acid | Resolution | Sensitivity | Final pattern | |
| | Polymer | Cross-linker | generator | (μmΦ) | (mJ/cm²) | Crack | Delamination |
| Example | A | NIKALAC | NAI-105 | 15 | 800 | no | no |
| 1 | | MW-390 | | | | | |
| Example | B | TMOM-BF | NAI-105 | 8 | 600 | no | no |
| 2 | | | | | | | |
| Example | C | NIKALAC | NAI-105 | 10 | 600 | no | no |
| 3 | | MW-270 | | | | | |
| Example | D | Compound*¹ | NAI-105 | 15 | 600 | no | no |
| 4 | | of | | | | | |
| | | the formula | | | | | |
| | | (5) | | | | | |
| Example | E | Epoxy | NAI-105 | 10 | 600 | no | no |
| 5 | | compound*² | | | | | |

*¹1,4-bis(acetoxymethyl)benzene
*²Bisphenol-F-diglycidyl ether

### Example 6

A negative photosensitive resin composition was prepared in such a way that (a) 10 g of the polymer A obtained in the Synthetic Example 1, (b) 1.5 g of a cross-linker “TMOM-BP” (Trade name), (c) 0.2 g of a photo-acid generator “NAI-105” (Trade name) and (d) 0.3 g of an organosilane compound (in the formula (14), R¹⁴ to R¹⁷=methyl groups, X¹, X²=propyl groups, R¹², R¹³=benzamide groups and k=1) were dissolved in (e) 17.25 g of γ-butyrolactone and then filtrated through a 0.2 μm of Teflon® filter.

This negative photosensitive insulating resin composition was spin-coated on 5-inch silicone substrate on which Cu layer was formed and then dried in an oven at 110° C. for 20 minutes to obtain a thin film having its thickness of 9.4 μm. Then the film was patterned by exposure of ultraviolet ray (wavelength=350−450 nm) via a photomask. After the exposure, it was baked in an oven at 100° C. for 10 minutes, then developed by immersing it in a 2.38% aqueous solution of TMAH for 2 minutes and subsequently rinsed with pure water for 3 minutes. As a result, an unexposed area in the negative photosensitive insulating resin composition film was dissolved off in the developing solution to obtain a negative pattern. SEM observation of the obtained pattern indicated that resolution to 8 μm of through-hole pattern was achieved at a sensitivity of 600 mJ/cm².

Next, the patterned wafer was baked under a nitrogen atmosphere in an oven at 100° C. for 1 hour and then at 220° C. for 1 hour for forming a benzoxazole ring to obtain a final pattern having a film thickness of 8 nm and exhibiting excellent properties such as heat resistance. SEM observation of the formed pattern did not indicate any crack and any delamination in the pattern.

### INDUSTRIAL APPLICABILITY

As is apparent from the above description, using the negative photosensitive insulation resin composition of this invention gives the film which can be developed with an alkaline aqueous solution, has excellent resolution and further the resin pattern formed from it having good adhesiveness for the substrate. Therefore, the negative photosensitive insulating resin composition of this invention can be used for the interlayer insulating film, surface protection film or the like of the semiconductor device.

This application claims priority to Japanese Patent Applications No. 2009-018194 filed Jan. 29, 2009 and No. 2009-144148 filed Jun. 17, 2009, the entire disclosures of which are incorporated herein.

1. A negative photosensitive insulating resin composition, wherein the resin composition comprises an alkali-soluble polymer having at least one repeating constitutional unit represented by the following general formula (1), a cross-linker and a photo-acid generator: 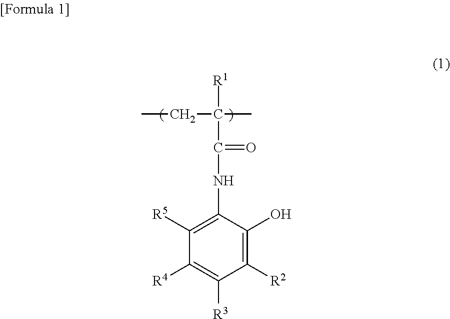
(In the formula (1), R¹ represents a hydrogen atom or a methyl group, and R² to R⁵ represent, independently each other, a hydrogen atom or a hydrocarbon group having 1 to 4 carbon atoms.)

2. The negative photosensitive insulating resin composition according to claim 1, wherein the cross-linker is a compound having the functional group represented by the following general formula (2), (3) or (4), a compound having the functional group represented by the following general formula (5) or a compound having an epoxy group. 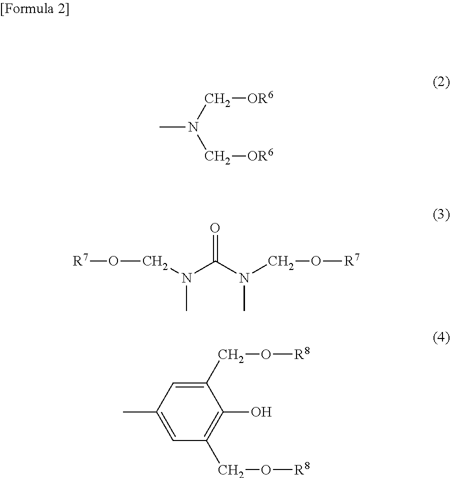
(In the formulae (2) to (4), R⁶, R⁷ and R⁸ represent an alkyl group having 1 to 6 carbon atoms respectively.) 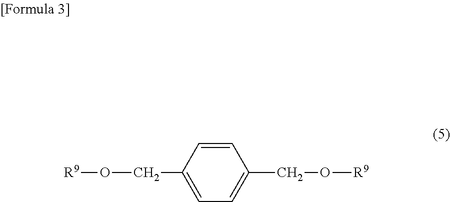
(In the formula (5), R⁹ represents an acyl group.)

3. The negative photosensitive insulating resin composition according to claim 2, wherein the compound having the functional group represented by the general formula (2) is a compound represented by the following general formula (6). 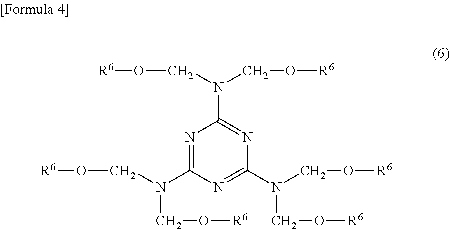
(In the formula (6), R⁶ represents an alkyl group having 1 to 6 carbon atoms.)

4. The negative photosensitive insulating resin composition according to claim 2, wherein the compound having the functional group represented by the general formula (3) is a compound represented by any one of the following general formulae (7) to (9). 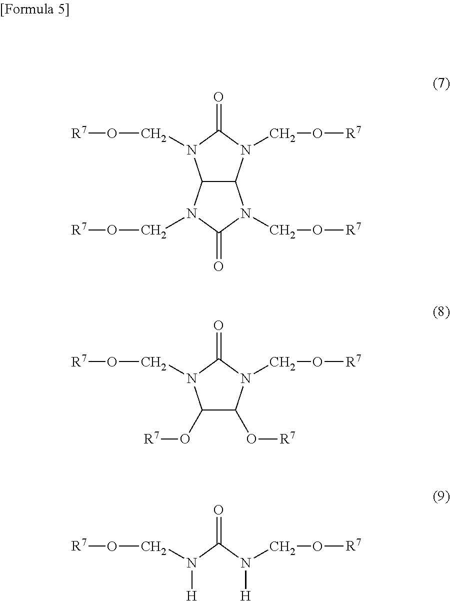
(In the formulae (7) to (9), R⁷ represents an alkyl group having 1 to 6 carbon atoms.)

5. The negative photosensitive insulating resin composition according to claim 2, wherein the compound having the functional group represented by the general formula (4) is a compound represented by the following general formula (10) or (11). 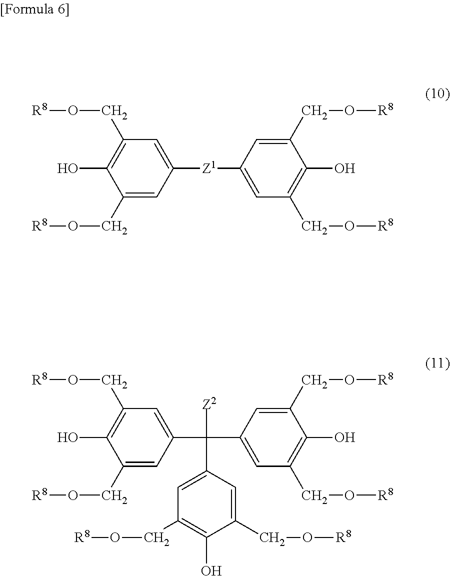
(In the formulae (10) and (11), R⁸ represents an alkyl group having 1 to 6 carbon atoms, Z¹ represents direct bond, —CH₂—, —C(CH₃)₂— or —C(CF₃)₂—, and Z² represents a hydrogen atom or a methyl group.)

6. The negative photosensitive insulating resin composition according to claim 1, wherein the polymer comprising the repeating constitutional unit represented by the formula (1) is a polymer further comprising one or more kinds of the repeating constitutional units selected from the group consisting of the repeating constitutional unit represented by the general formula (12) and the repeating unit represented by the general formula (13), with the repeating constitutional units represented by the general formula (1). 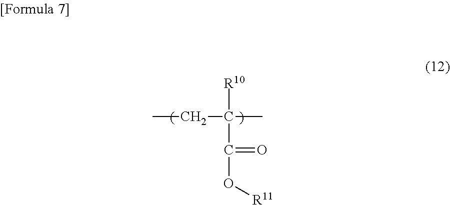
(In the formula (12), R¹⁰ represents a hydrogen atom or a methyl group, and R¹¹ represents an organic group having a lactone structure.) 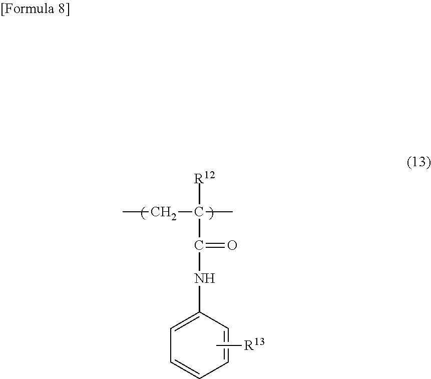
(In the formula (13), R¹² represents a hydrogen atom or a methyl group, and R¹³ represents a hydrogen atom, or an alkyl or alkoxy group having 1 to 4 carbon atoms.)

7. A method for patterning, comprising:
applying the negative photosensitive insulating resin composition according to claim 1 on a processed substrate;
pre-baking;
exposing;
after-exposure baking;
developing; and
post-baking.

8. The negative photosensitive insulating resin composition according to claim 2, wherein the polymer comprising the repeating constitutional unit represented by the formula (1) is a polymer further comprising one or more kinds of the repeating constitutional units selected from the group consisting of the repeating constitutional unit represented by the general formula (12) and the repeating unit represented by the general formula (13), with the repeating constitutional units represented by the general formula (1). 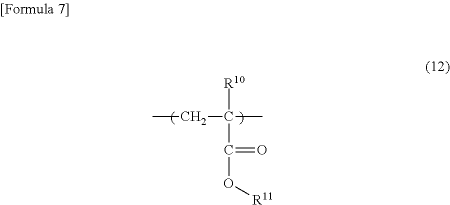
(In the formula (12), R¹⁰ represents a hydrogen atom or a methyl group, and R¹¹ represents an organic group having a lactone structure.) 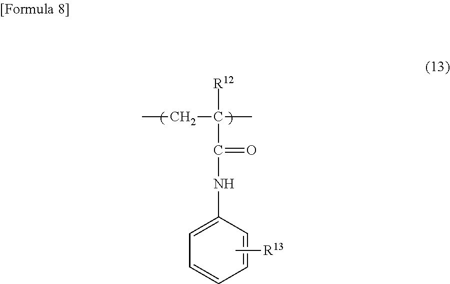
(In the formula (13), R¹² represents a hydrogen atom or a methyl group, and R¹³ represents a hydrogen atom, or an alkyl or alkoxy group having 1 to 4 carbon atoms.)

9. The negative photosensitive insulating resin composition according to claim 3, wherein the polymer comprising the repeating constitutional unit represented by the formula (1) is a polymer further comprising one or more kinds of the repeating constitutional units selected from the group consisting of the repeating constitutional unit represented by the general formula (12) and the repeating unit represented by the general formula (13), with the repeating constitutional units represented by the general formula (1). 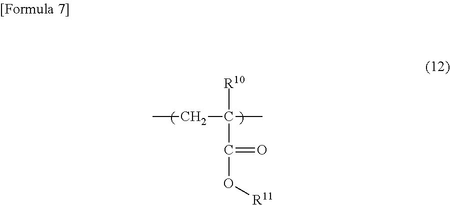
(In the formula (12), R¹⁰ represents a hydrogen atom or a methyl group, and R¹¹ represents an organic group having a lactone structure.) 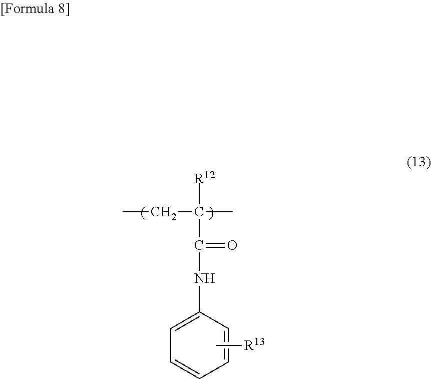
(In the formula (13), R¹² represents a hydrogen atom or a methyl group, and R¹³ represents a hydrogen atom, or an alkyl or alkoxy group having 1 to 4 carbon atoms.)

10. The negative photosensitive insulating resin composition according to claim 4, wherein the polymer comprising the repeating constitutional unit represented by the formula (1) is a polymer further comprising one or more kinds of the repeating constitutional units selected from the group consisting of the repeating constitutional unit represented by the general formula (12) and the repeating unit represented by the general formula (13), with the repeating constitutional units represented by the general formula (1). 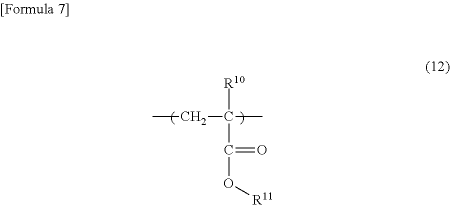
(In the formula (12), R¹⁰ represents a hydrogen atom or a methyl group, and R¹¹ represents an organic group having a lactone structure.) 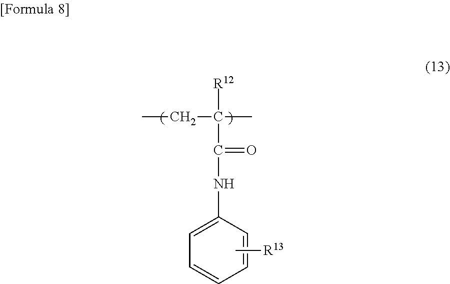
(In the formula (13), R¹² represents a hydrogen atom or a methyl group, and R¹³ represents a hydrogen atom, or an alkyl or alkoxy group having 1 to 4 carbon atoms.

11. The negative photosensitive insulating resin composition according to claim 5, wherein the polymer comprising the repeating constitutional unit represented by the formula (1) is a polymer further comprising one or more kinds of the repeating constitutional units selected from the group consisting of the repeating constitutional unit represented by the general formula (12) and the repeating unit represented by the general formula (13), with the repeating constitutional units represented by the general formula (1). 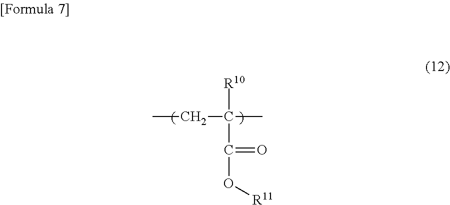
(In the formula (12), R¹⁰ represents a hydrogen atom or a methyl group, and R¹¹ represents an organic group having a lactone structure.) 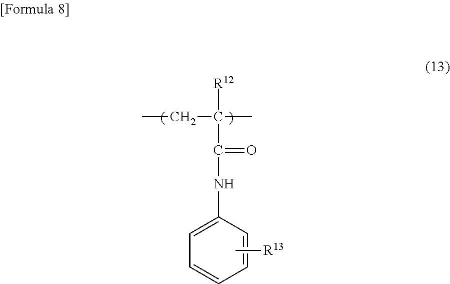
(In the formula (13), R¹² represents a hydrogen atom or a methyl group, and R¹³ represents a hydrogen atom, or an alkyl or alkoxy group having 1 to 4 carbon atoms.)

12. A method for patterning, comprising:
applying the negative photosensitive insulating resin composition according to claim 2 on a processed substrate;
pre-baking;
exposing;
after-exposure baking;
developing; and
post-baking.

13. A method for patterning, comprising:
applying the negative photosensitive insulating resin composition according to claim 3 on a processed substrate;
pre-baking;
exposing;
after-exposure baking;
developing; and
post-baking.

14. A method for patterning, comprising:
applying the negative photosensitive insulating resin composition according to claim 4 on a processed substrate;
pre-baking;
exposing;
after-exposure baking;
developing; and
post-baking.

15. A method for patterning, comprising:
applying the negative photosensitive insulating resin composition according to claim 5 on a processed substrate;
pre-baking;
exposing;
after-exposure baking;
developing; and
post-baking.

16. A method for patterning, comprising:
applying the negative photosensitive insulating resin composition according to claim 6 on a processed substrate;
pre-baking;
exposing;
after-exposure baking;
developing; and
post-baking.
